(19) United States
(12) Patent Application Publication
(10) Pub. No.: US 2013/0164533 A1
(43) Pub. Date: Jun. 27, 2013

(54) PIEZOELECTRIC CERAMIC AND METHOD OF MANUFACTURING THE SAME

(71) Applicants: National Institute for Materials Science, Tsukuba-shi (JP); MURATA MANUFACTURING CO., LTD., Nagaokakyo-shi (JP)

(72) Inventors: Tohru Suzuki, Tsukuba-shi (JP); Tetsuo Uchikoshi, Tsukuba-shi (JP); Yoshio Sakka, Tsukuba-shi (JP); Yasunari Miwa, Nagaokakyo-shi (JP); Shinichiro Kawada, Nagaokakyo-shi (JP); Masahiko Kimura, Nagaokakyo-shi (JP)

(73) Assignees: MURATA MANUFACTURING CO., LTD., Nagaokakyo-shi (JP); National Institute for Materials Science, Tsukuba-shi (JP)

(21) Appl. No.: 13/771,895

(22) Filed: Feb. 20, 2013

Related U.S. Application Data
(63) Continuation of application No. PCT/JP2011/068744, filed on Aug. 19, 2011.

(30) Foreign Application Priority Data
Aug. 26, 2010 (JP) 2010-189469

(51) Int. Cl. H01L 41/187; H01L 41/333

(52) U.S. Cl. CPC H01L 41/1878; H01L 41/333
USPC 428/402; 264/405

(57) ABSTRACT

A piezoelectric ceramic having excellent electrical characteristics, and in which all of three crystallographic axes are oriented is obtained by slip cast or sheet forming a ceramic slurry containing plate-shaped ceramic particles in magnetic field. The degree of orientation of a first axis (for example, a c axis) calculated with the Lotgering method based on an X-ray diffraction (XRD) pattern in a prescribed cross-section of this piezoelectric ceramic is not less than 0.30. With a cross-section where the degree of orientation of the first axis indicates a maximum value being defined as a reference plane, the degree of orientation of a second axis (for example, an a axis) calculated with the Lotgering method based on an X-ray diffraction pattern in a cross-section orthogonal to this reference plane is not less than 0.20. The degree of orientation of the second axis is represented by a value in such a cross-section that the degree of orientation of the second axis attains to a maximum value, among cross-sections orthogonal to the reference plane.

This is a continuation of application Serial No. PCT/JP2011/068744, filed Aug. 19, 2011, the entire contents of which are incorporated herein by reference.

### TECHNICAL FIELD

This invention relates to a piezoelectric material, in particular, piezoelectric ceramic in which crystals are oriented, and to a method of manufacturing the same.

### BACKGROUND ART

It is known that electrical characteristics of piezoelectric ceramic are improved by orienting crystals of piezoelectric ceramic. In order to enhance the crystal orientation properties of piezoelectric ceramic, for example, a technique described in PTL 1 has been proposed. With the technique described in PTL 1, a piezoelectric ceramic high in crystal orientation properties is obtained by slip casting or sheet forming a ceramic slurry containing plate-shaped ceramic particles.

In addition, a technique described in PTL 2 has also been proposed as another means for obtaining high crystal orientation properties. With the technique described in PTL 2, a piezoelectric ceramic high in crystal orientation properties is obtained by slip casting or sheet forming ceramic slurry in magnetic field.

### Patent Literature

PTL 1: Japanese Patent Laying-Open No. 2006-225188
PTL 2: Japanese Patent Laying-Open No. 2004-6704

### SUMMARY OF INVENTION

### Technical Problem

Simply by slip casting or sheet forming plate-shaped ceramic particles as in the technique in PTL 1, however, only one axis having shape anisotropy among crystallographic axes of ceramic particles could be oriented. Similarly, in forming in magnetic field as in PTL 2, only an easy axis (one axis) of crystallographic axes of ceramic particles could be oriented. Disadvantageously, the technique in PTL 1 or the technique in PTL 2 could orient only one of the crystallographic axes of ceramic particles. Therefore, it has been difficult to meet the needs for higher piezoelectric characteristics and it has also been difficult to improve electrical characteristics of piezoelectric ceramic.

Thus, a primary object of this invention is to provide piezoelectric ceramic excellent in electrical characteristics, in which all three of crystallographic axes of piezoelectric ceramic particles are oriented, and a method of manufacturing the same.

### Solution to Problem

This invention is directed to piezoelectric ceramic containing plate-shaped ceramic particles, characterized in that the degree of orientation of a first axis calculated with the Lotgering method based on an X-ray diffraction pattern in a prescribed cross-section of the piezoelectric ceramic is not less than 0.30, with a cross-section where the degree of orientation of the first axis indicates a maximum value being defined as a reference plane, the degree of orientation of a second axis calculated with the Lotgering method based on an X-ray diffraction pattern in a cross-section orthogonal to the reference plane is not less than 0.20, and the degree of orientation of the second axis is represented by a value in such a cross-section that the degree of orientation of the second axis attains to a maximum value, among cross-sections orthogonal to the reference plane.

With this invention, the piezoelectric ceramic has a cross-section where the degrees of orientation of two of the three axes of crystallographic axes of the piezoelectric ceramic particles indicate the respective maximum values. In addition, since remaining one axis is also oriented accordingly, a piezoelectric ceramic in which all of the three axes of the crystallographic axes of the piezoelectric ceramic particles are oriented is obtained.

In addition, the plate-shaped ceramic particles in this invention are preferably free from shape anisotropy when viewed in a direction in parallel to a c axis.

In the case that there is no shape anisotropy when the plate-shaped ceramic particles are viewed in a direction in parallel to the c axis, the plate-shaped ceramic particles are densely aligned, so that anisotropy of mechanical strength of ceramic is lessened, handling is facilitated, and piezoelectric characteristics are stabilized. Furthermore, from a point of view of manufacturing, the making of plate-shaped ceramic particles is facilitated and piezoelectric ceramic can be prepared with low cost.

In addition, preferably, the plate-shaped ceramic particles have an average particle size not greater than 20 μm in this invention.

In the case where the plate-shaped ceramic particles have such a small average particle size as 20 μm or smaller, the plate-shaped ceramic particles are densely aligned, so that piezoelectric characteristics are enhanced and piezoelectric characteristics are stabilized. Furthermore, from the point of view of the manufacturing method, in the case where the plate-shaped ceramic particles have such a small average particle size as 20 μm or smaller, orientation is readily achieved by applying magnetic field in a prescribed direction and thus piezoelectric ceramic can be prepared with low cost.

In addition, the plate-shaped ceramic particles are preferably composed of a bismuth layered compound.

In this invention, the load on an environment is lower than in the case of a lead compound causing serious environmental pollution, in the case where a bismuth layered compound is employed for the plate-shaped ceramic particles.

In addition, this invention is directed to a method of manufacturing piezoelectric ceramic, including preparing ceramic slurry containing plate-shaped ceramic particles, forming the ceramic slurry into a sheet with a sheet forming method or a slip cast forming method, and applying magnetic field to the sheet-shaped ceramic slurry, which is characterized in that the direction of application of the magnetic field is in a prescribed direction in substantially the same plane where the sheet-shaped ceramic slurry is located.

Since the ceramic slurry is formed into a sheet by sheet forming or slip cast forming and magnetic field is applied to the ceramic slurry formed into a sheet, the axis having shape anisotropy and the easy axis among three crystallographic axes of piezoelectric ceramic particles are oriented. Since remaining one axis is also oriented accordingly, a piezoelectric ceramic in which all of the three of the crystallographic axes of the piezoelectric ceramic particles are oriented is obtained. Furthermore, by sheet forming or slip cast forming the ceramic slurry, the plate-shaped ceramic particles can readily be aligned in layers.

### Advantageous Effects of Invention

According to this invention, a piezoelectric ceramic in which all of three axes of crystallographic axes of piezoelectric ceramic particles are oriented can readily be obtained. Therefore, for example, piezoelectric ceramic excellent in such electrical characteristics as a high electromechanical coupling coefficient, stable frequency-temperature characteristics, a high dielectric constant, low loss, and a great piezoelectric d constant can be obtained.

The foregoing and other objects, features, and advantages of this invention will become more apparent from the following description of embodiments for carrying out the invention when taken in conjunction with the drawings.

### BRIEF DESCRIPTION OF DRAWINGS

FIG. 1 shows an image picked up by an SEM of granular particle powders of CaBi₄Ti₄O₁₅.

FIG. 2 shows an image picked up by an SEM of granular particle powders of CaBi₄Ti₄O₁₅-0.31 wt % MnO.

FIG. 3 shows an image picked up by an SEM of plate-shaped particle powders of CaBi₄Ti₄O₁₅.

FIG. 4 is an illustrative diagram for illustrating a forming step in a slip cast forming method.

FIG. 5 is a schematic diagram showing a T plane having a direction of gravity as a normal and an S2 plane which is a plane in parallel to the direction of gravity and having a direction of application of magnetic field as a normal, in a sintered object.

FIG. 6 is an XRD chart of the T plane and an XRD chart of the S2 plane of a CaBi₄Ti₄O₁₅ ceramic sintered object (sample No. 1).

FIG. 7 is an XRD chart of the T plane and an XRD chart of the S2 plane of a CaBi₄Ti₄O₁₅ ceramic sintered object (sample No. 2).

FIG. 8 is an XRD chart of the T plane and an XRD chart of the S2 plane of a CaBi₄Ti₄O₁₅ ceramic sintered object (sample No. 3).

FIG. 9 is an XRD chart of the T plane and an XRD chart of the S2 plane of a CaBi₄Ti₄O₁₅ ceramic sintered object (sample No. 4).

FIG. 10 is an XRD chart of the T plane and an XRD chart of the S2 plane of a CaBi₄Ti₄O₁₅ ceramic sintered object (sample No. 5).

FIG. 11 is an XRD chart of the T plane and an XRD chart of the S2 plane of a CaBi₄Ti₄O₁₅-0.31wt % MnO ceramic sintered object (sample No. 6).

FIG. 12 is an XRD chart of the T plane and an XRD chart of the S2 plane of a ceramic sintered object (sample No. 7) containing CaBi₄Ti₄O₁₅-0.31wt % MnO.

FIG. 13 is an XRD chart of the T plane and an XRD chart of the S2 plane of a ceramic sintered object (sample No. 8) containing CaBi₄Ti₄O₁₅-0.31wt % MnO.

FIG. 14 is an XRD chart of the T plane and an XRD chart of the S2 plane of a ceramic sintered object (sample No. 9) containing CaBi₄Ti₄O₁₅-0.31wt % MnO.

FIG. 15 is an XRD chart of the T plane and an XRD chart of the S2 plane of a ceramic sintered object (sample No. 10) containing CaBi₄Ti₄O₁₅-0.31wt % MnO.

FIG. 16 shows an image picked up by an SEM of plate-shaped particle powders of Bi₄Ti₃O₁₂-0.06 wt % MnO.

FIG. 17 is an XRD chart of the T plane and an XRD chart of the S2 plane of a Bi₄Ti₃O₁₂-0.06wt % MnO ceramic sintered object (sample No. 11).

FIG. 18 is an XRD chart of the T plane and an XRD chart of the S2 plane of a Bi₄Ti₃O₁₂-0.06wt % MnO ceramic sintered object (sample No. 12).

FIG. 19 is an XRD chart of the T plane and an XRD chart of the S2 plane of a Bi₄Ti₃O₁₂-0.06wt % MnO ceramic sintered object (sample No. 13).

FIG. 20 shows an image picked up by an SEM of Bi₃TiNbO₉-0.08wt % MnO plate-shaped particle powders.

FIG. 21 is an XRD chart of the T plane and an XRD chart of the S2 plane of a Bi₃TiNbO₉-0.08wt % MnO ceramic sintered object (sample No. 14).

FIG. 22 is an XRD chart of the T plane and an XRD chart of the S2 plane of a Bi₃TiNbO₉-0.08wt % MnO ceramic sintered object (sample No. 15).

FIG. 23 is an XRD chart of the T plane and an XRD chart of the S2 plane of a Bi₃TiNbO₉-0.08wt % MnO ceramic sintered object (sample No. 16).

FIG. 24 is an illustrative diagram for illustrating a forming step with a sheet forming method.

### REFERENCE SIGNS LIST

1 ceramic slurry
10 alumina plate
12 filter paper
14 cast
20 carrier film
22 application apparatus
24 magnetic field application apparatus
28a, 28b transportation roller
B magnetic field
P direction of extension
G direction of gravity

### DESCRIPTION OF EMBODIMENTS

Piezoelectric Ceramic

A piezoelectric ceramic according to the present invention is piezoelectric ceramic formed of ceramic particles containing plate-shaped ceramic particles. The degree of orientation of a first axis (for example, a c axis) calculated with the Lotgering method based on an X-ray diffraction (XRD) pattern in a prescribed cross-section of the piezoelectric ceramic is not less than 0.30. It is noted that the Lotgering method will be described later in detail. Then, with a cross-section where the degree of orientation of the first axis indicates a maximum value being defined as a reference plane, degree of orientation of a second axis (for example, an a axis) calculated with the Lotgering method based on an X-ray diffraction pattern in a cross-section orthogonal to this reference plane is not less than 0.20. The degree of orientation of the second axis is represented by a value in such a cross-section that the degree of orientation of the second axis attains to a maximum value, among cross-sections orthogonal to the reference plane.

In other words, the piezoelectric ceramic according to the present invention has such a cross-section that the degree of orientation of the first axis calculated with the Lotgering method indicates the maximum value based on the X-ray diffraction (XRD) pattern in the prescribed cross-section of the piezoelectric ceramic. The piezoelectric ceramic has such a cross-section that, with this cross-section being defined as the reference plane, the degree of orientation of the second axis calculated with the Lotgering method based on the X-ray diffraction pattern in the cross-section orthogonal to this reference plane indicates the maximum value. The degree of orientation of the first axis is not less than 0.30 and the degree of orientation of the second axis is not less than 0.20.

Namely, the piezoelectric ceramic according to the present invention has such a cross-section that degrees of orientation of two axes of three axes of crystallographic axes of piezoelectric ceramic particles indicate respective maximum values. Since the remaining one axis is also oriented accordingly, a piezoelectric ceramic in which all of the three axes of the crystallographic axes of the piezoelectric ceramic particles are oriented is obtained. Therefore, for example, piezoelectric ceramic excellent in such electrical characteristics as a high electromechanical coupling coefficient, stable frequency-temperature characteristics, a high dielectric constant, low loss, and a great piezoelectric d constant can be obtained.

By employing piezoelectric ceramic particles having no shape anisotropy when the piezoelectric ceramic is viewed from above (when the piezoelectric ceramic is viewed in a direction in parallel to the c axis) as plate-shaped ceramic particles, the plate-shaped ceramic particles are densely aligned, so that anisotropy of mechanical strength of piezoelectric ceramic can be lessened, handling can be facilitated, and piezoelectric characteristics can be stabilized. Furthermore, from a point of view of manufacturing, as will be described later in detail, the making of the plate-shaped ceramic particles is facilitated and piezoelectric ceramic can be prepared with low cost.

Moreover, by setting the average particle size of the plate-shaped ceramic particles to 20 μm or smaller, the plate-shaped ceramic particles are densely aligned. Thus, the piezoelectric characteristics of the piezoelectric ceramic can be enhanced and piezoelectric characteristics can be stabilized. Furthermore, from a point of view of manufacturing, orientation is readily achieved by applying magnetic field in a prescribed direction and thus piezoelectric ceramic can be prepared with low cost since the plate-shaped ceramic particles have such a small average particle size as 20 μm or smaller.

Further, by employing a bismuth layered compound for the plate-shaped ceramic particles, the load on an environment can be lower than in the case of a lead compound causing serious environmental pollution.

Method of Manufacturing Piezoelectric Ceramic

An embodiment of a method of manufacturing piezoelectric ceramic according to the present invention will now be described by way of example of a CaBi₄Ti₄O₁₅ ceramic.

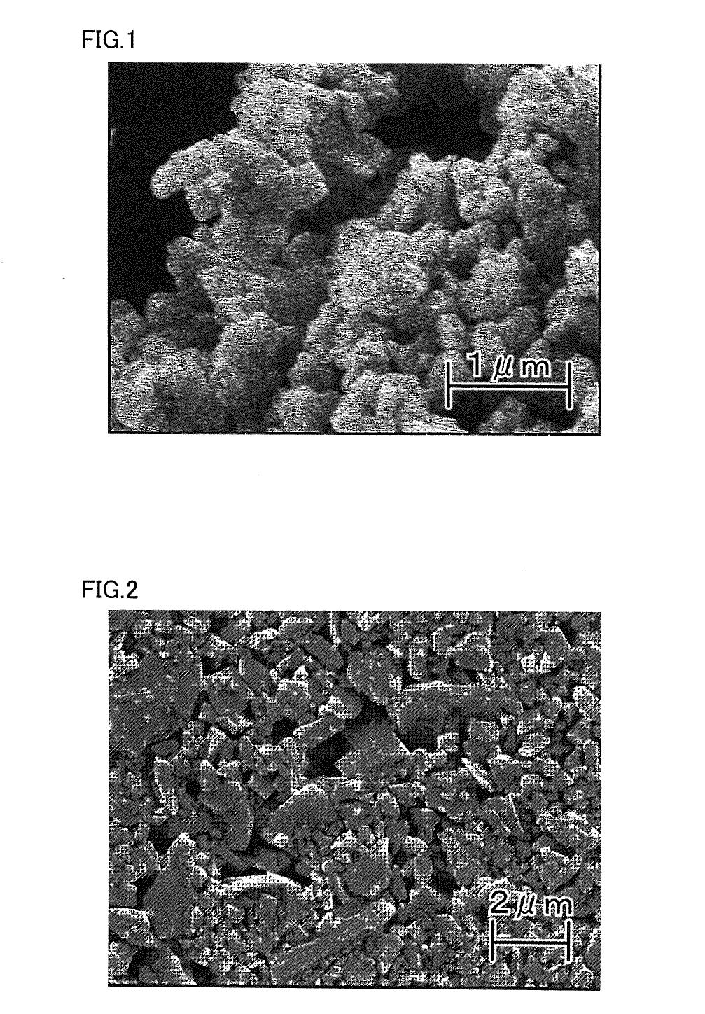

Initially, CaBi₄Ti₄O₁₅ granular particle powders, CaBi₄Ti₄O₁₅-0.31wt % MnO granular particle powders, and CaBi₄Ti₄O₁₅ plate-shaped particle powders, which are source materials, are prepared. The CaBi₄Ti₄O₁₅ granular particle powders were prepared as follows. Calcium hydroxide, bismuth oxide, and titanium oxide were blended to obtain a composition of CaBi₄Ti₄O₁₅, and they were mixed and stirred with a ball mill with the use of water as a solvent. After the thus obtained ceramic slurry was dried, it was provisionally fired at 900° C. in an electric furnace. The resultant provisionally fired powders were crushed with a ball mill for 100 hours with the use of water as a solvent followed by drying, to thereby obtain CaBi₄Ti₄O₁₅ granular particle powders. FIG. 1 shows an SEM image of the CaBi₄Ti₄O₁₅ granular particle powders.

In addition, CaBi₄Ti₄O₁₅-0.31wt % MnO granular particle powders were prepared as follows. Calcium hydroxide, bismuth oxide, titanium oxide, and manganese carbonate were blended to obtain a composition of CaBi₄Ti₄O₁₅-0.31wt % MnO, and they were mixed and stirred with a ball mill with the use of water as a solvent. Manganese carbonate was employed for promoting sintering to be performed in a subsequent step, and after provisional firing, it is converted to manganese oxide. After the thus obtained ceramic slurry was dried, it was provisionally fired at 1200° C. The resultant provisionally fired powders were crushed with a ball mill for 100 hours with the use of water as a solvent followed by drying, to thereby obtain CaBi₄Ti₄O₁₅-0.31wt % MnO granular particle powders. It is noted that the amount of addition (0.3wt %) of “MnO” is a value when it is assumed that base composition “CaBi₄Ti₄O₁₅” is defined as 100wt %. FIG. 2 shows an SEM image of the CaBi₄Ti₄O₁₅-0.31wt % MnO granular particle powders.

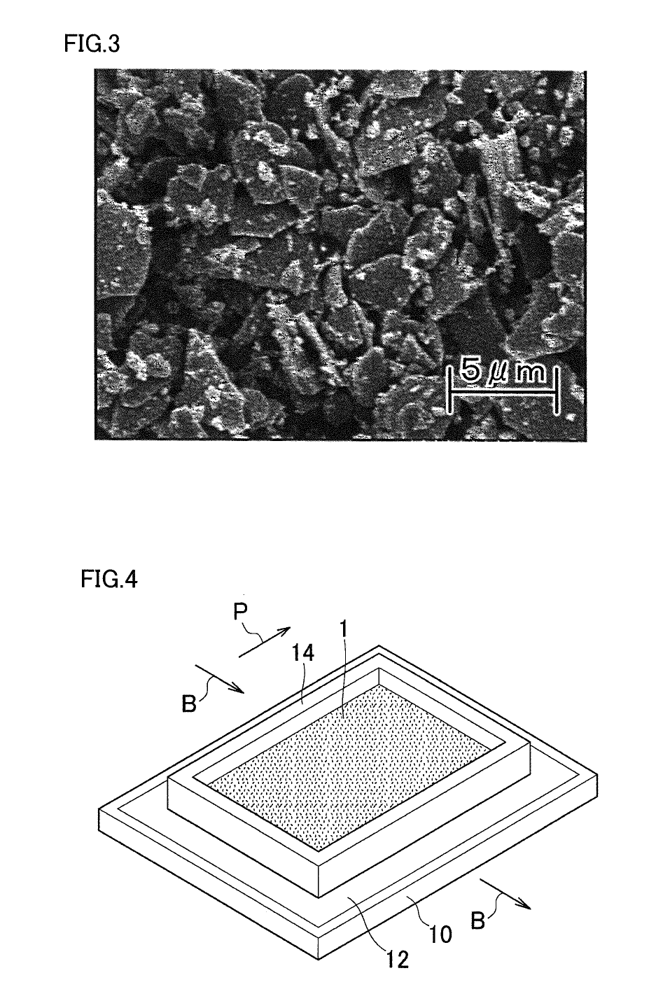

CaBi₄Ti₄O₁₅ plate-shaped particle powders were prepared as follows. Calcium hydroxide, bismuth oxide, and titanium oxide were blended to obtain composition of CaBi₄Ti₄O₁₅, and they were mixed and stirred with a ball mill with the use of water as a solvent. After the thus obtained ceramic slurry was dried, it was provisionally fired at 900° C. The resultant provisionally fired powders and KCl were mixed at a weight ratio of 1:1 and the mixture was subjected to heat treatment at 1000° C. for 12 hours in an alumina crucible. After heat treatment, KCl was washed away with water, and the resultant powders were crushed with a ball mill with the use of water as a solvent followed by drying, to thereby obtain the CaBi₄Ti₄O₁₅ plate-shaped particle powders. FIG. 3 shows an SEM image of the CaBi₄Ti₄O₁₅ plate-shaped particle powders. The CaBi₄Ti₄O₁₅ plate-shaped particle preferably has an aspect ratio L/H, which is the ratio between a length dimension L and a thickness dimension H, of not less than 3. This is because when the aspect ratio is less than 3, the shape anisotropy of the CaBi₄Ti₄O₁₅ plate-shaped particles is less and it becomes difficult to align orientations of the CaBi₄Ti₄O₁₅ plate-shaped particles by making use of shape anisotropy at the time of forming in a subsequent step.

The CaBi₄Ti₄O₁₅ granular particle powders, the CaBi₄Ti₄O₁₅-0.31wt % MnO granular particle powders, and the CaBi₄Ti₄O₁₅ plate-shaped particle powders above were mixed at ratios shown for samples No. 1 to No. 10 in Table 1, distilled water in a volume of 5.7 times as much as a volume of the mixed powders was added, a dispersant was mixed in an amount of 0.8wt % with respect to 100wt % of the powders, and mixing for 5 minutes was performed by using an ultrasonic homogenizer. The reason why not only the CaBi₄Ti₄O₁₅ plate-shaped particle powders but also the granular particle powders are mixed for use is because dense ceramic can be obtained after sintering. The dispersant is used for avoiding adhesion among powders. It is noted that a “granular particle/plate-shaped particle ratio” in Table 1 is represented as a weight ratio.

TABLE 1

| | | | | | | Degree of Orientation | | |
|---|---|---|---|---|---|---|---|---|
| | | | Granular | | | Based on Lotgering | | |
| | | | Particle/Plate- | | | Method | | |
| | | Composition | Shaped Particle | Applied | | Degree of | Degree of | |
| | Composition of | of Plate- | Ratio | Magnetic | Firing | Orientation | Orientation | |
| | Granular | Shaped | [Weight | Field | Temperature | of c Axis at | of a, b Axes | Determination |
| Sample | Particles | Particles | Ratio] | [T] | [° C.] | T Plane | at S2 Plane | of Pass/Failure |
| No. 1 | CaBi₄Ti₄O₁₅ | — | 100/0 | 12 | 1150 | 0.028 | 0.025 | Failure |
| No. 2 | CaBi₄Ti₄O₁₅ | CaBi₄Ti₄O₁₅ | 70/30 | 12 | 1200 | 0.582 | 0.349 | Pass |
| No. 3 | CaBi₄Ti₄O₁₅ | CaBi₄Ti₄O₁₅ | 70/30 | 0 | 1200 | 0.512 | 0.033 | Failure |
| No. 4 | CaBi₄Ti₄O₁₅ | CaBi₄Ti₄O₁₅ | 50/50 | 12 | 1200 | 0.564 | 0.324 | Pass |
| No. 5 | CaBi₄Ti₄O₁₅ | CaBi₄Ti₄O₁₅ | 50/50 | 0 | 1200 | 0.539 | 0.047 | Failure |
| No. 6 | CaBi₄Ti₄O₁₅ | — | 100/0 | 0 | 1200 | 0.139 | 0.028 | Failure |
| | 0.31 wt % MnO | | | | | | | |
| No. 7 | CaBi₄Ti₄O₁₅— | CaBi₄Ti₄O₁₅ | 95/5 | 12 | 1200 | 0.636 | 0.309 | Pass |
| | 0.31 wt % MnO | | | | | | | |
| No. 8 | CaBi₄Ti₄O₁₅— | CaBi₄Ti₄O₁₅ | 70/30 | 12 | 1200 | 0.683 | 0.231 | Pass |
| | 0.31 wt % MnO | | | | | | | |
| No. 9 | CaBi₄Ti₄O₁₅— | CaBi₄Ti₄O₁₅ | 50/50 | 12 | 1200 | 0.716 | 0.377 | Pass |
| | 0.31 wt % MnO | | | | | | | |
| No. 10 | CaBi₄Ti₄O₁₅— | CaBi₄Ti₄O₁₅ | 50/50 | 0 | 1200 | 0.436 | 0.021 | Failure |
| | 0.31 wt % MnO | | | | | | | |

By slip cast forming the thus obtained ceramic slurry, the CaBi₄Ti₄O₁₅ plate-shaped ceramic particles were readily aligned in layers. As shown in FIG. 4, a frame-shaped cast 14 is set on an unglazed alumina plate 10 on which filter paper 12 is placed. Ceramic slurry 1 is poured to extend from one side to the other side (in a direction shown with an arrow P) in a direction of length in this cast 14 and cast into a sheet. The alumina plate 10 is porous and water-absorbent, and it is used for absorbing distilled water contained in ceramic slurry 1. Then, during a period from pouring of ceramic slurry 1 until solidification of ceramic slurry 1, a prescribed magnetic field B was applied to form a sheet-shaped ceramic compact. The direction of the application of magnetic field B is set to one direction in substantially the same plane where sheet-shaped ceramic slurry 1 is located. In the present example, an in-plane direction of sheet-shaped ceramic slurry 1 is orthogonal to a direction of gravity and the direction of application of magnetic field B is set to a direction orthogonal to a direction of extension P of sheet-shaped ceramic slurry 1 in substantially the same plane where this sheet-shaped ceramic slurry 1 is located. With regard to intensity of magnetic field B, 12 tesla was applied in the present example. By holding and firing the thus obtained compact at a temperature shown in Table 1 for 2 hours, a sintered object was obtained.

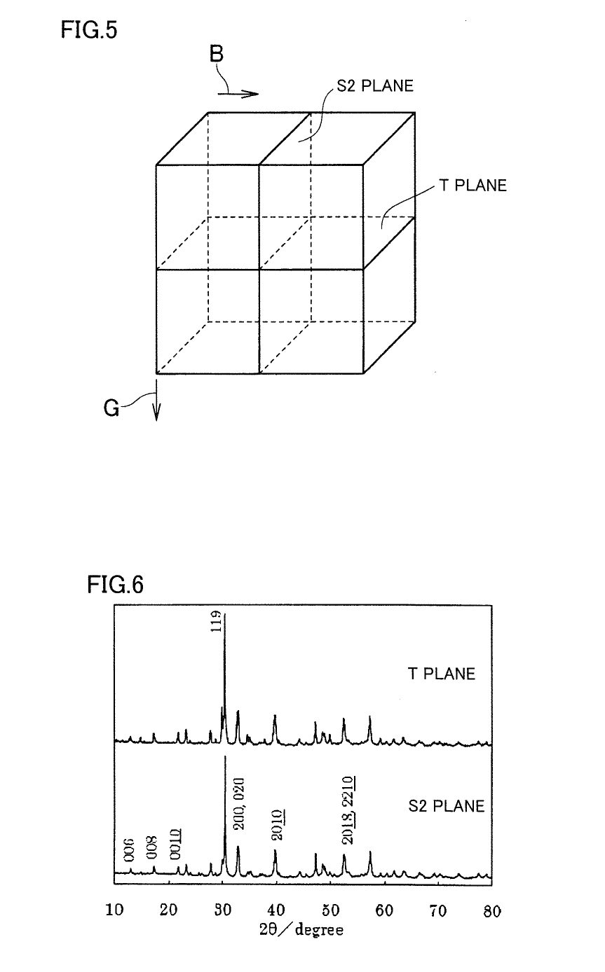

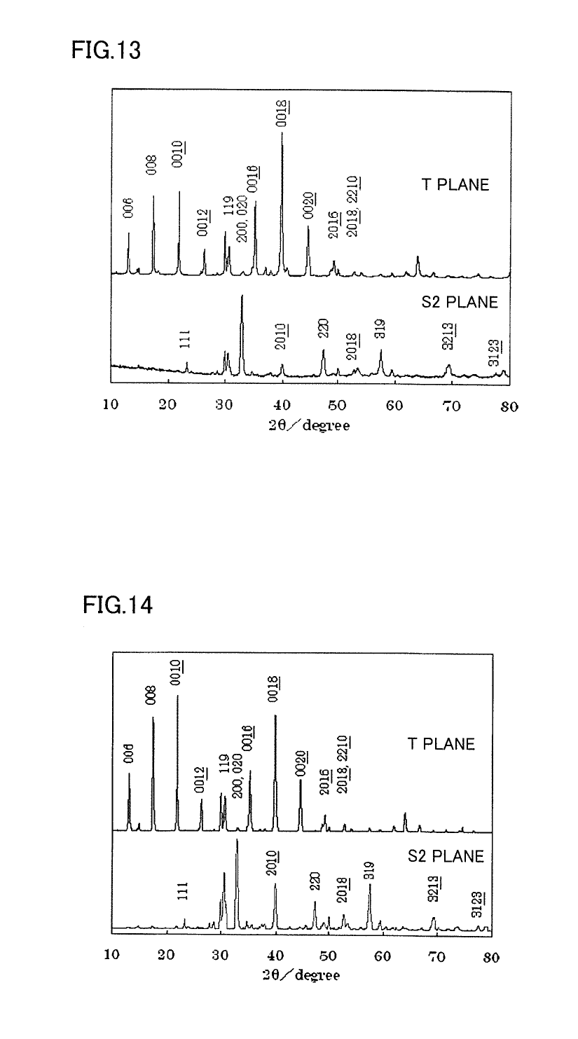

As shown in FIG. 5, the obtained sintered objects (samples No. 1 to No. 10) were cut along a plane having a direction of gravity G as a normal (T plane) and a plane in parallel to direction of gravity G and having a direction of application of magnetic field B as a normal (S2 plane), and each plane (the T plane, the S2 plane) was subjected to measurement with an X-ray diffraction (XRD) measurement apparatus having Cu as a target. FIGS. 6 to 15 show measurement results. FIGS. 6 to 15 each show an XRD chart (an XRD pattern) of the T plane in an upper portion, and in a lower portion, an XRD chart (an XRD pattern) of the S2 plane.

Sample No. 1 shown in FIG. 6 is a sintered object which does not contain plate-shaped ceramic particles in spite of slip cast forming of the ceramic slurry in magnetic field. As shown in the upper portion of FIG. 6, a c axis (a (001) axis) orientation property at the T plane was not found, and as shown in the lower portion, a axis (a (100) axis), b axis (a (010) axis) orientation properties at the S2 plane were not found either. It is noted that, with the present material, the a axis and the b axis are substantially equivalent to each other and distinction therebetween is difficult. Though the a axis is considered as an easy axis, the a axis and the b axis are substantially equivalent to each other and distinction therebetween is difficult. Therefore, in the XRD chart for the S2 plane as well, an orientation property was determined for one peak intensity (a peak intensity of “200, 020” shown in FIG. 6 and the like), without distinction between the a axis and the b axis.

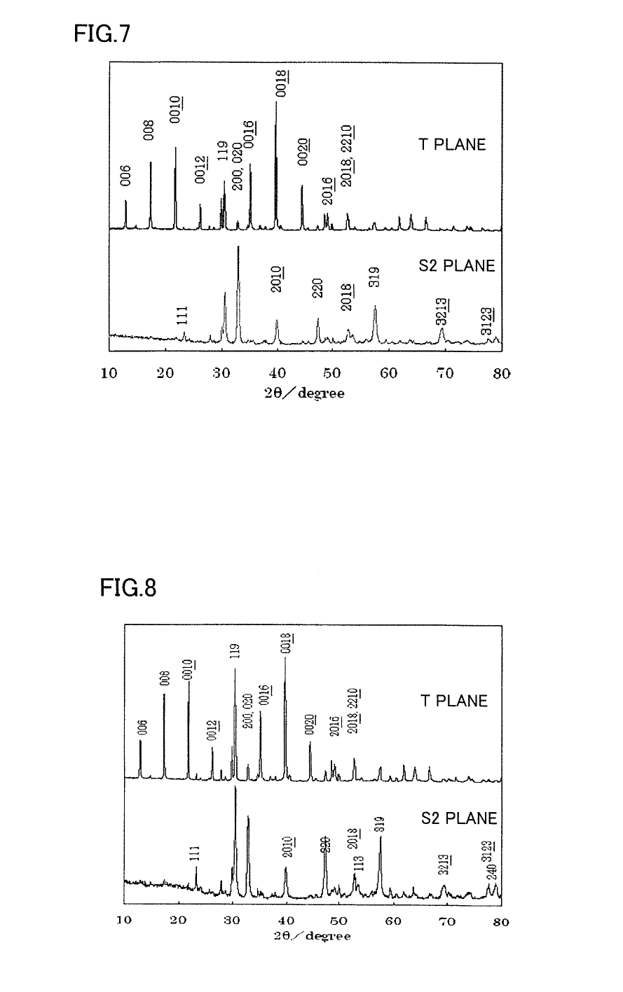

Sample No. 2 shown in FIG. 7 is a sintered object obtained by slip cast forming the ceramic slurry containing plate-shaped ceramic particles in magnetic field. As shown in the upper portion of FIG. 7, a c axis ((001) axis) orientation property at the T plane was found, and as shown in the lower portion, a axis ((100) axis), b axis ((010) axis) orientation properties at the S2 plane were also found.

Sample No. 3 shown in FIG. 8 is a sintered object containing plate-shaped ceramic particles but obtained without slip cast forming ceramic slurry in magnetic field. As shown in the upper portion of FIG. 8, a c axis ((001) axis) orientation property at the T plane was found, however, as shown in the lower portion, a axis ((100) axis), b axis ((010) axis) orientation properties at the S2 plane were not found.

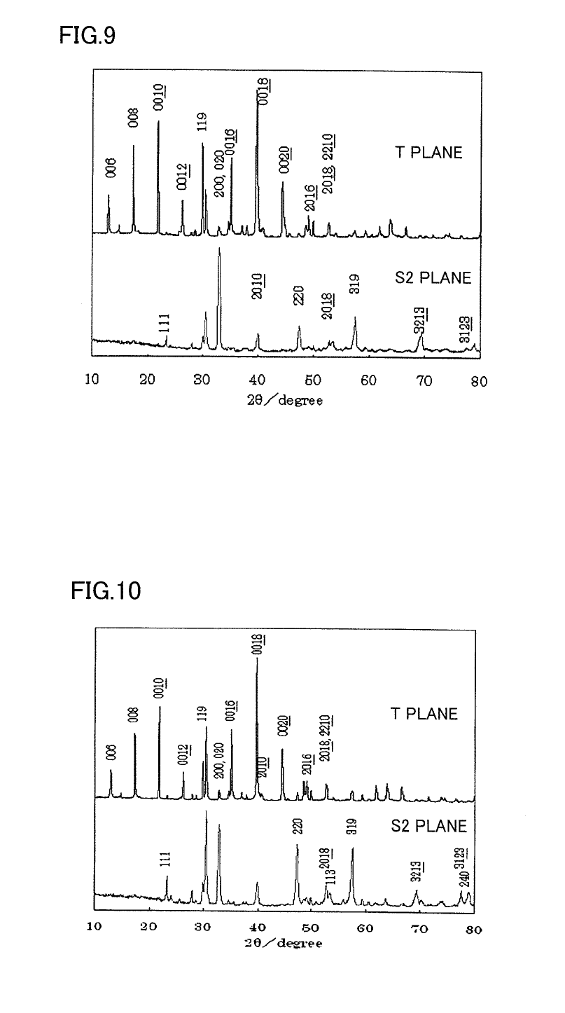

Sample No. 4 shown in FIG. 9 is a sintered object obtained by slip cast forming ceramic slurry containing plate-shaped ceramic particles in magnetic field. As shown in the upper portion of FIG. 9, a c axis ((001) axis) orientation property at the T plane was found, and as shown in the lower portion, a axis ((100) axis), b axis ((010) axis) orientation properties at the S2 plane were also found.

Sample No. 5 shown in FIG. 10 is a sintered object containing plate-shaped ceramic particles but obtained without slip cast forming ceramic slurry in magnetic field. As shown in the upper portion of FIG. 10, a c axis ((001) axis) orientation property at the T plane was found, however, as shown in the lower portion, a axis ((100) axis), b axis ((010) axis) orientation properties at the S2 plane were not found.

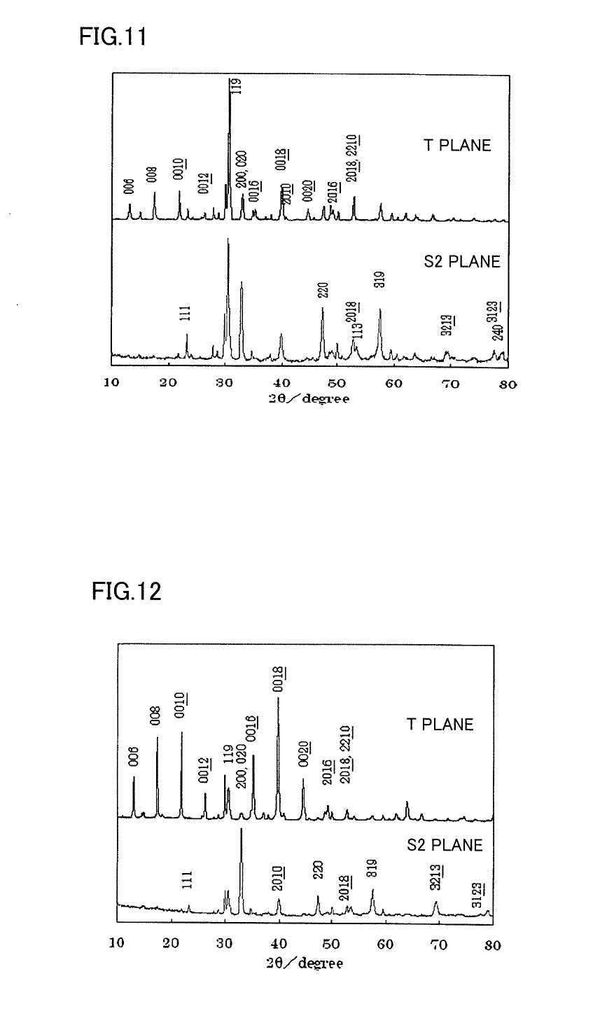

Sample No. 6 shown in FIG. 11 is a sintered object not containing plate-shaped ceramic particles and further obtained without slip casting ceramic slurry in magnetic field. As shown in the upper portion of FIG. 11, a c axis ((001) axis) orientation property at the T plane was not found, and as shown in the lower portion, a axis ((100) axis), b axis ((010) axis) orientation properties at the S2 plane were not found either.

Samples No. 7 to No. 9 shown in FIGS. 12 to 14, respectively, are sintered objects obtained by slip cast forming ceramic slurry containing plate-shaped ceramic particles in magnetic field. As shown in the upper portions of FIGS. 12 to 14, respectively, a c axis ((001) axis) orientation property at the T plane was found, and as shown in the lower portions, a axis ((100) axis), b axis ((010) axis) orientation properties at the S2 plane were also found.

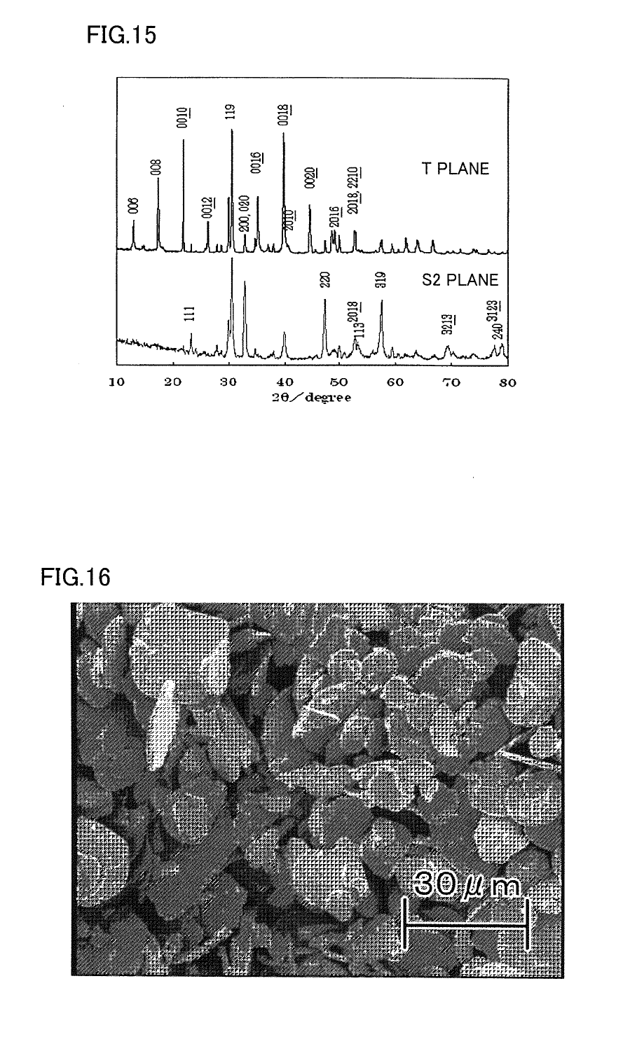

Sample No. 10 shown in FIG. 15 is a sintered object containing plate-shaped ceramic particles but obtained without slip cast forming ceramic slurry in magnetic field. As shown in the upper portion of FIG. 15, a c axis ((001) axis) orientation property at the T plane was found, however, as shown in the lower portion, a axis ((100) axis), b axis ((010) axis) orientation properties at the S2 plane were not found.

Table 1 also shows a degree of orientation of the c axis calculated based on the XRD chart at the T plane and a degree of orientation of the a axis, the b axis calculated based on the XRD chart at the S2 plane. It is noted that the degree of orientation was calculated from Equation (1) below with the Lotgering method, with an indexable peak within a range of 2θ=10 to 80° in the XRD chart being taken into consideration. In calculation of a degree of orientation, the aforementioned prepared CaBi₄Ti₄O₁₅ granular particle powders were adopted as a reference sample.

$$Degree of orientation F = \frac{\frac{Σ I ( HKL )}{Σ I ( hkl )} - \frac{Σ {I}_{0} ( HKL )}{Σ {I}_{0} ( hkl )}}{1 - \frac{Σ {I}_{0} ( HKL )}{Σ {I}_{0} ( hkl )}} \times 100 \qquad ( 1 )$$

Here, ΣI (HKL) represents the total sum of X-ray peak intensities at a specific crystal plane (HKL) in a ceramic sintered object to be evaluated, and ΣI (hkl) represents the total sum of X-ray peak intensities at all crystal planes (hkl) of the ceramic sintered object to be evaluated. In addition, since the lattice constants of the a axis and the b axis are substantially equal to each other and cannot be separated from each other, a degree of orientation at the S2 plane was calculated with a crystal being handled as a tetragonal crystal. Moreover, ΣI₀ (HKL) represents the total sum of X-ray peak intensities at a specific crystal plane (HKL) in the reference sample, and ΣI₀ (hkl) represents the total sum of X-ray peak intensities at all crystal planes (hkl) of the reference sample.

As seen in Table 1, the sintered objects of sample No. 2, sample No. 4, and samples No. 7 to No. 9 can each obtain a high degree of orientation of the c axis at the T plane, which is not less than 0.564, and also a high degree of orientation of the a axis, and the b axis at the S2 plane, which is not less than 0.231. This is because the c axis was oriented in the direction of gravity at the time of slip cast forming by employing ceramic slurry containing plate-shaped ceramic particles. In addition, this is because the a axis (the (100) axis) considered as an easy axis was oriented in a direction of application of magnetic field by forming ceramic slurry into a sheet by slip cast forming and applying magnetic field to the ceramic slurry formed into a sheet. Consequently, three-axis-oriented piezoelectric ceramic in which the c axis was oriented in the direction of gravity at the time of slip cast forming and the a axis was oriented in the direction of application of magnetic field was obtained.

In contrast, the sintered object of sample No. 1 had a degree of orientation of the c axis at the T plane which was as low as 0.028 and a degree of orientation of the a axis, and the b axis at the S2 plane which was also as low as 0.025. This is because plate-shaped ceramic particles were not used in spite of slip cast forming of ceramic slurry in magnetic field, which resulted in insufficient orientation of the c axis and orientation of the a axis, the b axis.

In addition, the sintered objects of sample No. 3, sample No. 5, and sample No. 10 each obtained a high degree of orientation of the c axis at the T plane, which was not less than 0.436, but, they each had a low degree of orientation of the a axis, the b axis at the S2 plane, which was not higher than 0.047. This is because although these samples contained plate-shaped ceramic particles, the ceramic slurry was formed into a sheet at the time of slip cast forming and a magnetic field was not applied to the ceramic slurry formed into a sheet, which resulted in insufficient orientation of the a axis considered as an easy axis in a direction of application of magnetic field, in spite of orientation of the c axis in the direction of gravity.

Moreover, the sintered object of sample No. 6 had a degree of orientation of the c axis at the T plane which was as low as 0.139 and also a degree of orientation of the a axis, and the b axis at the S2 plane which was as low as 0.028. This is because the sample did not contain plate-shaped ceramic particles, and the ceramic slurry was formed into a sheet by slip cast forming, but a magnetic field was not applied to the ceramic slurry formed into a sheet, which resulted in insufficient orientation of the c axis and the a axis, the b axis.

From the foregoing, it can be seen that piezoelectric ceramic in which all of three axes of crystallographic axes of piezoelectric ceramic particles are oriented can readily be obtained by forming a ceramic slurry containing CaBi₄Ti₄O₁₅ plate-shaped ceramic particles into a sheet by slip cast forming and applying a magnetic field to the ceramic slurry formed into a sheet.

Another embodiment of a method of manufacturing piezoelectric ceramic according to the present invention will further be described by way of example of a Bi₄Ti₃O₁₂ ceramic.

Initially, Bi₄Ti₃O₁₂-0.06wt % MnO granular particle powders and Bi₄Ti₃O₁₂-0.06wt % MnO plate-shaped particle powders (which are source materials) are prepared. The Bi₄Ti₃O₁₂-0.06wt % MnO granular particle powders were prepared as follows. Bismuth oxide, titanium oxide, and manganese carbonate were blended to obtain a composition of Bi₄Ti₃O₁₂-0.06wt % MnO, and they were mixed and stirred with a ball mill with the use of water as a solvent. After the thus obtained ceramic slurry was dried, it was provisionally fired at 900° C. The resultant provisionally fired powders were crushed with a ball mill for 16 hours with the use of water as a solvent followed by drying, to thereby obtain Bi₄Ti₃O₁₂-0.06wt % MnO granular particle powders.

Bi₄Ti₃O₁₂-0.06wt % MnO plate-shaped particle powders were prepared as follows. Bismuth oxide, titanium oxide, and manganese carbonate were blended to obtain composition of Bi₄Ti₃O₁₂-0.06wt % MnO, and they were mixed and stirred with a ball mill with the use of water as a solvent. After the thus obtained ceramic slurry was dried, it was provisionally fired at 900° C. in an electric furnace. The resultant provisionally fired powders and KCl were mixed at a weight ratio of 1:1 and the mixture was subjected to heat treatment at 1000° C. for 12 hours in an alumina crucible. After the heat treatment, KCl was washed away with water, and the resultant powders were crushed with a ball mill with the use of water as a solvent followed by drying, to thereby obtain the Bi₄Ti₃O₁₂-0.06wt % MnO plate-shaped particle powders. FIG. 16 shows an SEM image of the Bi₄Ti₃O₁₂-0.06wt % MnO plate-shaped particle powders. Here, a Bi₄Ti₃O₁₂-0.06wt % MnO plate-shaped particle preferably has aspect ratio L/H, which is a ratio between length dimension L and thickness dimension H, not less than 3.

The Bi₄Ti₃O₁₂-0.06wt % MnO granular particle powders and the Bi₄Ti₃O₁₂-0.06wt % MnO plate-shaped particle powders above were mixed at ratios shown for samples No. 11 to No. 13 in Table 2, distilled water in a volume 5.7 times as much as a volume of the mixed powders was added, a dispersant was mixed by 0.8wt % with respect to 100wt % of the powders, and mixing for 5 minutes was performed by using an ultrasonic homogenizer.

TABLE 2

| | | | | | | Degree of Orientation | | |
|---|---|---|---|---|---|---|---|---|
| | | | Granular | | | Based on Lotgering | | |
| | | | Particle/Plate- | | | Method | | |
| | | Composition | Shaped Particle | Applied | | Degree of | Degree of | |
| | Composition of | of Plate- | Ratio | Magnetic | Firing | Orientation | Orientation | |
| | Granular | Shaped | [Weight | Field | Temperature | of c Axis at | of a, b Axes | Determination |
| Sample | Particles | Particles | Ratio] | [T] | [° C.] | T Plane | at S2 Plane | of Pass/Failure |
| No. 11 | Bi₄Ti₃O₁₂— | Bi₄Ti₃O₁₂— | 70/30 | 12 | 1100 | 0.678 | 0.486 | Pass |
| | 0.06 wt % MnO | 0.06 wt % MnO | | | | | | |
| No. 12 | Bi₄Ti₃O₁₂— | Bi₄Ti₃O₁₂— | 70/30 | 0 | 1100 | 0.605 | 0.170 | Failure |
| | 0.06 wt % MnO | 0.06 wt % MnO | | | | | | |
| No. 13 | Bi₄Ti₃O₁₂— | Bi₄Ti₃O₁₂— | 100/0 | 12 | 1100 | 0.239 | 0.328 | Failure |
| | 0.06 wt % MnO | 0.06 wt % MnO | | | | | | |

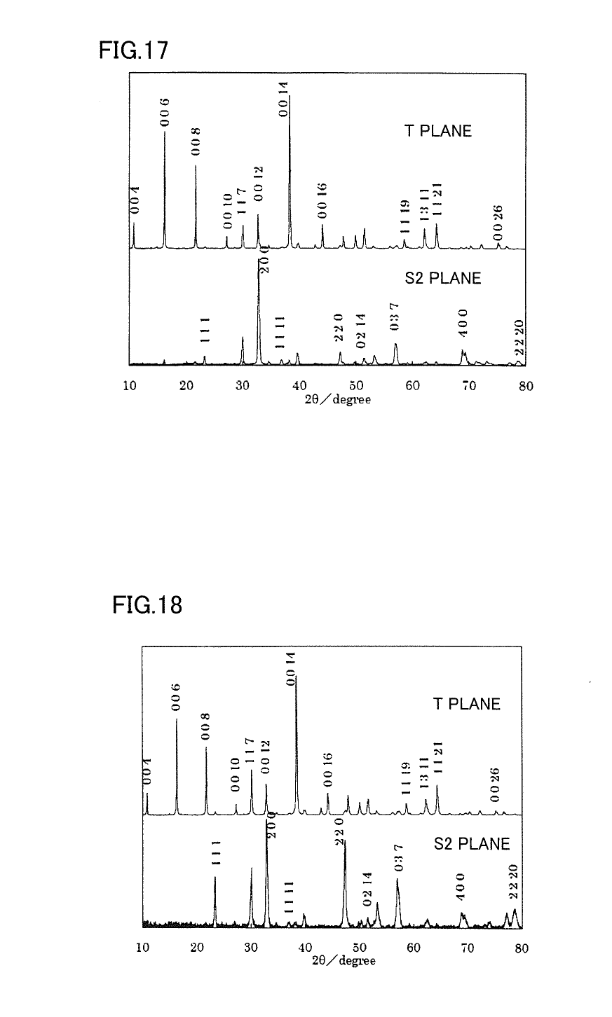

By slip cast forming the thus obtained ceramic slurry, the Bi₄Ti₃O₁₂-0.06wt % MnO plate-shaped ceramic particles were readily aligned in layers. As shown in FIG. 4, ceramic slurry 1 is poured to extend from one side to the other side (in the direction shown with arrow P) in the direction of length in cast 14 and cast into a sheet. Then, during a period from pouring of ceramic slurry 1 until solidification of ceramic slurry 1, a prescribed magnetic field B was applied to form a sheet-shaped ceramic compact. The direction of application of magnetic field B is set to one direction in substantially the same plane where sheet-shaped ceramic slurry 1 is located. In the present example, the in-plane direction of sheet-shaped ceramic slurry 1 is orthogonal to the direction of gravity and the direction of application of magnetic field B is set to a direction orthogonal to direction of extension P of sheet-shaped ceramic slurry 1 in substantially the same plane where this sheet-shaped ceramic slurry 1 is located. With regard to intensity of magnetic field B, 12 tesla was applied in the present example. By holding and firing the thus obtained compact at the temperature shown in Table 2 for 2 hours, a sintered object was obtained. The obtained sintered objects (samples No. 11 to No. 13) were cut along a plane having direction of gravity G as a normal (T plane) and a plane in parallel to the direction of gravity and having the direction of application of magnetic field as a normal (S2 plane), and each plane (the T plane, the S2 plane) was subjected to measurement with an X-ray diffraction (XRD) measurement apparatus having Cu as a target. FIGS. 17 to 19 show measurement results. FIGS. 17 to 19 each show an XRD chart (an XRD pattern) of the T plane in an upper portion, and in a lower portion, an XRD chart (an XRD pattern) of the S2 plane.

Sample No. 11 shown in FIG. 17 is a sintered object obtained by slip cast forming ceramic slurry containing plate-shaped ceramic particles in magnetic field. As shown in the upper portion of FIG. 17, a c axis ((001) axis) orientation property at the T plane was found, and as shown in the lower portion, a axis ((100) axis), b axis ((010) axis) orientation properties at the S2 plane were also found.

Sample No. 12 shown in FIG. 18 is a sintered object containing plate-shaped ceramic particles but obtained without slip cast forming ceramic slurry in magnetic field. As shown in the upper portion of FIG. 18, a c axis ((001) axis) orientation property at the T plane was found, but, as shown in the lower portion, a axis ((100) axis), b axis ((010) axis) orientation properties at the S2 plane were not found.

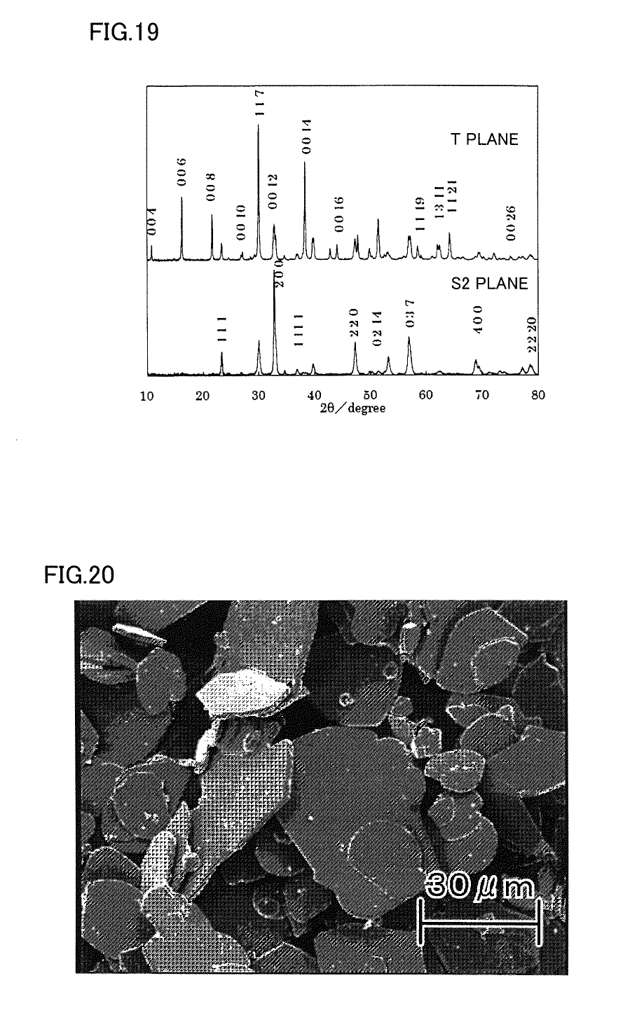

Sample No. 13 shown in FIG. 19 is a sintered object obtained by slip cast forming ceramic slurry in magnetic field but not containing plate-shaped ceramic particles. As shown in the upper portion of FIG. 19, a c axis ((001) axis) orientation property at the T plane was not found, but, as shown in the lower portion, a axis ((100) axis), b axis ((010) axis) orientation properties at the S2 plane were found.

Table 2 also shows the degree of orientation of the c axis calculated based on the XRD chart at the T plane and the degree of orientation of the a axis, and the b axis calculated based on the XRD chart at the S2 plane. It is noted that the degree of orientation was calculated from Equation (1) above with the Lotgering method, with an indexable peak within a range of 2θ=10 to 80° in the XRD chart being taken into consideration. In calculation of a degree of orientation, the aforementioned prepared Bi₄Ti₃O₁₂-0.06wt % MnO granular particle powders were adopted as a reference sample. In addition, since the lattice constants of the a axis and the b axis are substantially equal to each other and cannot be separated from each other, the degree of orientation at the S2 plane was calculated with a crystal being handled as a tetragonal crystal.

As seen in Table 2, the sintered object of sample No. 11 can obtain a high degree of orientation of the c axis at the T plane which is 0.678 and also a high degree of orientation of the a axis, the b axis at the S2 plane which is 0.486. This is because the c axis was oriented in the direction of gravity at the time of slip cast forming by employing ceramic slurry containing plate-shaped ceramic particles. In addition, this is because the a axis (the (100) axis), considered as an easy axis, was oriented in a direction of application of magnetic field by forming ceramic slurry into a sheet by slip cast forming and applying magnetic field to the ceramic slurry formed into a sheet. Consequently, three-axis-oriented piezoelectric ceramic in which the c axis was oriented in the direction of gravity at the time of slip cast forming and the a axis was oriented in the direction of application of magnetic field was obtained.

In contrast, although the sintered object of sample No. 12 obtained a high degree of orientation of the c axis at the T plane which was 0.605, it had a degree of orientation of the a axis, and the b axis at the S2 plane which was as low as 0.170. This is because although the sample contained plate-shaped ceramic particles, the ceramic slurry was formed into a sheet at the time of slip cast forming and magnetic field was not applied to the ceramic slurry formed into a sheet, which resulted in insufficient orientation of the a axis, which is an easy axis, in a direction of application of magnetic field, in spite of orientation of the c axis in the direction of gravity.

Moreover, the sintered object of sample No. 13 had a degree of orientation of the c axis at the T plane which was as low as 0.239, although it had a high degree of orientation of the a axis, and the b axis at the S2 plane which was 0.328. This is because although ceramic slurry was slip cast formed in magnetic field, plate-shaped ceramic particles were not employed, which resulted in insufficient orientation of the c axis in spite of orientation of the a axis.

From the foregoing, it can be seen that piezoelectric ceramic in which all of three axes of crystallographic axes of piezoelectric ceramic particles are oriented can readily be obtained by forming ceramic slurry containing Bi₄Ti₃O₁₂-0.06wt % MnO plate-shaped ceramic particles into a sheet by slip cast forming and applying magnetic field to the ceramic slurry formed into a sheet.

Another embodiment of a method of manufacturing piezoelectric ceramic according to the present invention will further be described by way of example of Bi₃TiNbO₉-0.08wt % MnO ceramic.

Initially, Bi₃TiNbO₉-0.08wt % MnO granular particle powders and Bi₃TiNbO₉-0.08wt % MnO plate-shaped particle powders, which are source materials, are prepared. The Bi₃TiNbO₉-0.08wt % MnO granular particle powders were prepared as follows. Bismuth oxide, titanium oxide, niobium oxide, and manganese carbonate were blended to obtain composition of Bi₃TiNbO₉-0.08wt % MnO, and they were mixed and stirred with a ball mill with the use of water as a solvent. After the thus obtained slurry was dried, it was provisionally fired at 900° C. by using an electric furnace. The resultant provisionally fired powders were crushed with a ball mill for 16 hours with the use of water as a solvent followed by drying, to thereby obtain Bi₃TiNbO₉-0.08wt MnO granular particle powders.

Bi₃TiNbO₉-0.08wt % MnO plate-shaped particle powders were prepared as follows. Bismuth oxide, titanium oxide, niobium oxide, and manganese carbonate were blended to obtain composition of Bi₃TiNbO₉-0.08wt % MnO, and they were mixed and stirred with a ball mill with the use of water as a solvent. After the thus obtained ceramic slurry was dried, it was provisionally fired at 900° C. The resultant provisionally fired powders and KCl were mixed at a weight ratio of 1:1 and the mixture was subjected to heat treatment at 1000° C. for 12 hours in an alumina crucible. After heat treatment, KCl was washed away with water, and the resultant powders were crushed with a ball mill with the use of water as a solvent followed by drying, to thereby obtain the Bi₃TiNbO₉-0.08wt % MnO plate-shaped particle powders. FIG. 20 shows an SEM image of the Bi₃TiNbO₉-0.08wt % MnO plate-shaped particle powders. Here, a Bi₃TiNbO₉-0.08wt % MnO plate-shaped particle preferably has aspect ratio L/H, which is a ratio between length dimension L and thickness dimension H, not less than 3.

The Bi₃TiNbO₉-0.08wt % MnO granular particle powders and the Bi₃TiNbO₉-0.08wt % MnO plate-shaped particle powders above were mixed at ratios shown for samples No. 14 to No. 16 in Table 3, distilled water in a volume 5.7 time as much as a volume of the mixed powders was added, a dispersant was mixed by 0.8wt % with respect to 100wt % of the powders, and mixing for 5 minutes was performed by using an ultrasonic homogenizer.

TABLE 3

| | | | | | | Degree of Orientation | | |
|---|---|---|---|---|---|---|---|---|
| | | | Granular | | | Based on Lotgering | | |
| | | | Particle/Plate- | | | Method | | |
| | | Composition | Shaped Particle | Applied | | Degree of | Degree of | |
| | Composition of | of Plate- | Ratio | Magnetic | Firing | Orientation | Orientation | |
| | Granular | Shaped | [Weight | Field | Temperature | of c Axis at | of a, b Axes | Determination |
| Sample | Particles | Particles | Ratio] | [T] | [° C.] | T Plane | at S2 Plane | of Pass/Failure |
| No. 14 | Bi₃TiNbO₉— | Bi₃TiNbO₉— | 70/30 | 12 | 1100 | 0.761 | 0.664 | Pass |
| | 0.08 wt % MnO | 0.08 wt % MnO | | | | | | |
| No. 15 | Bi₃TiNbO₉— | Bi₃TiNbO₉— | 70/30 | 0 | 1100 | 0.411 | 0.096 | Failure |
| | 0.08 wt % MnO | 0.08 wt % MnO | | | | | | |
| No. 16 | Bi₃TiNbO₉— | Bi₃TiNbO₉— | 100/0 | 12 | 1100 | 0.103 | 0.230 | Failure |
| | 0.08 wt % MnO | 0.08 wt % MnO | | | | | | |

By slip cast forming the thus obtained ceramic slurry, the Bi₃TiNbO₉-0.08wt % MnO plate-shaped ceramic particles were readily aligned in layers. As shown in FIG. 4, ceramic slurry 1 is poured to extend from one side to the other side (in the direction shown with arrow P) in the direction of length in cast 14 and cast into a sheet. Then, during a period from pouring of ceramic slurry 1 until solidification of ceramic slurry 1, a prescribed magnetic field B was applied to form a sheet-shaped ceramic compact. The direction of application of magnetic field B is set to one direction in substantially the same plane where sheet-shaped ceramic slurry 1 is located. In the present example, an in-plane direction of sheet-shaped ceramic slurry 1 is orthogonal to the direction of gravity and the direction of application of magnetic field B is set to a direction orthogonal to direction of extension P of sheet-shaped ceramic slurry 1 in substantially the same plane where this sheet-shaped ceramic slurry 1 is located. With regard to intensity of magnetic field B, 12 tesla was applied in the present example. By holding and firing the thus obtained compact at a temperature shown in Table 3 for 2 hours, a sintered object was obtained.

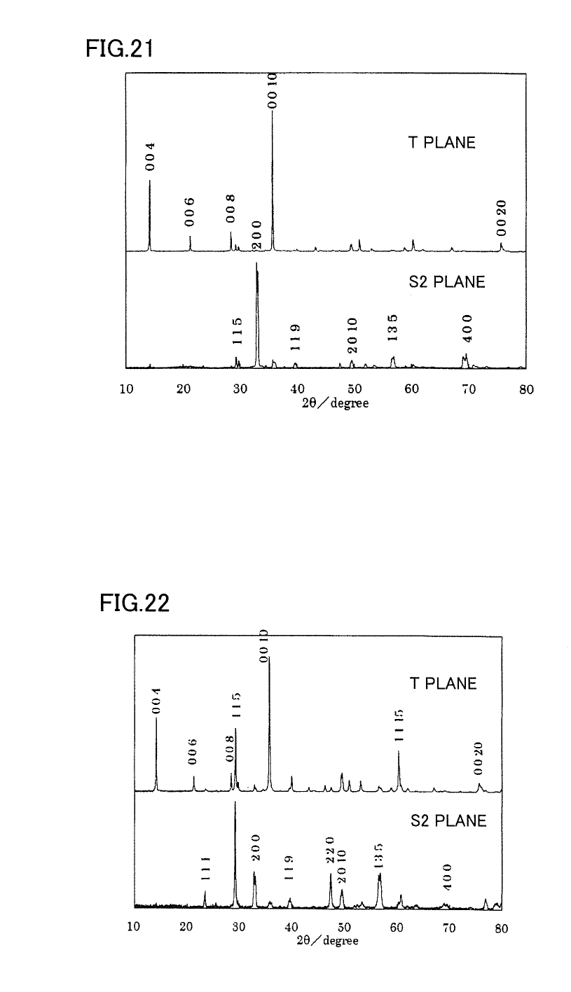

The obtained sintered objects (samples No. 14 to No. 16) were cut along a plane having the direction of gravity as a normal (T plane) and a plane in parallel to the direction of gravity and having the direction of application of magnetic field as a normal (S2 plane), and each plane (the T plane, the S2 plane) was subjected to measurement with an X-ray diffraction (XRD) measurement apparatus having Cu as a target. FIGS. 21 to 23 show measurement results. FIGS. 21 to 23 each show an XRD chart (an XRD pattern) of the T plane in an upper portion, and in a lower portion, an XRD chart (an XRD pattern) of the S2 plane.

Sample No. 14 shown in FIG. 21 is a sintered object obtained by slip cast forming ceramic slurry containing plate-shaped ceramic particles in magnetic field. As shown in the upper portion of FIG. 21, a c axis ((001) axis) orientation property at the T plane was found, and as shown in the lower portion, a axis ((100) axis), b axis ((010) axis) orientation properties at the S2 plane were also found.

Sample No. 15 shown in FIG. 22 is a sintered object containing plate-shaped ceramic particles but obtained without slip cast forming ceramic slurry in magnetic field. As shown in the upper portion of FIG. 22, a c axis ((001) axis) orientation property at the T plane was found, but, as shown in the lower portion, a axis ((100) axis), b axis ((010) axis) orientation properties at the S2 plane were not found.

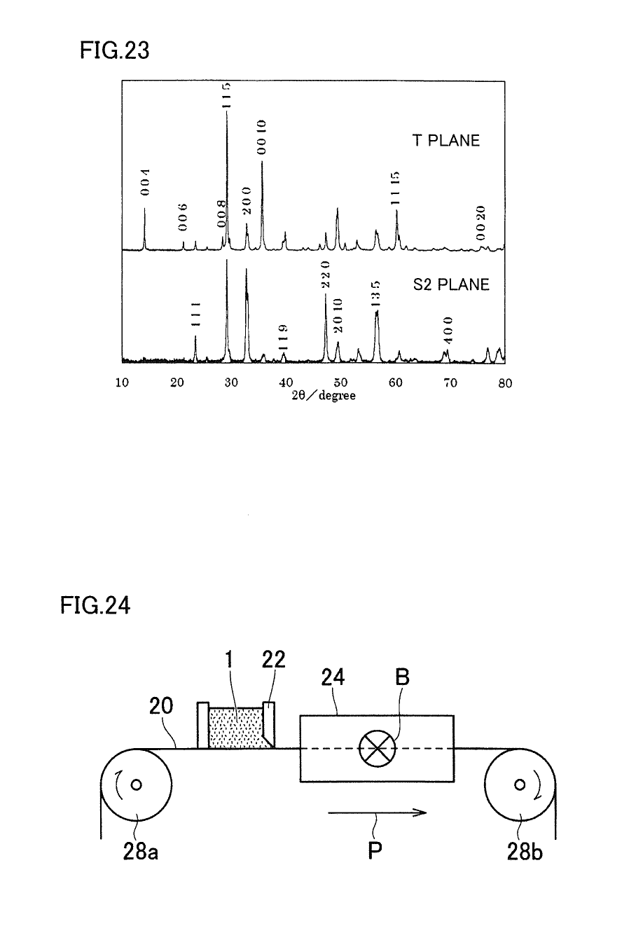

Sample No. 16 shown in FIG. 23 is a sintered object obtained by slip cast forming ceramic slurry in magnetic field but not containing plate-shaped ceramic particles. As shown in the upper portion of FIG. 23, a c axis ((001) axis) orientation property at the T plane was not found, but, as shown in the lower portion, a axis ((100) axis), b axis ((010) axis) orientation properties at the S2 plane were found.

Table 3 also shows the degree of orientation of the c axis calculated based on the XRD chart at the T plane and a degree of orientation of the a axis, and the b axis calculated based on the XRD chart at the S2 plane. It is noted that the degree of orientation was calculated from Equation (1) above with the Lotgering method, with an indexable peak within a range of 2θ=10 to 80° in the XRD chart being taken into consideration. In calculation of a degree of orientation, the aforementioned prepared Bi₃TiNbO₉-0.08wt % MnO granular particle powders were adopted as a reference sample. In addition, since the lattice constants of the a axis and the b axis are substantially equal to each other and cannot be separated from each other, a degree of orientation at the S2 plane was calculated with a crystal being handled as a tetragonal crystal.

As seen in Table 3, the sintered object of sample No. 14 can obtain a high degree of orientation of the c axis at the T plane which is 0.761 and also a high degree of orientation of the a axis, and the b axis at the S2 plane which is 0.664. This is because the c axis was oriented in the direction of gravity at the time of slip cast forming by employing ceramic slurry containing plate-shaped ceramic particles. In addition, this is because the a axis ((100) axis) considered as an easy axis was oriented in a direction of application of magnetic field by forming ceramic slurry into a sheet by slip cast forming and applying magnetic field to the ceramic slurry formed into a sheet. Consequently, three-axis-oriented piezoelectric ceramic in which the c axis was oriented in the direction of gravity at the time of slip cast forming and the a axis was oriented in the direction of application of magnetic field was obtained.

In contrast, although the sintered object of sample No. 15 obtained a high degree of orientation of the c axis at the T plane which was 0.411, it had a degree of orientation of the a axis, the b axis at the S2 plane which was as low as 0.096. This is because although the sample contained plate-shaped ceramic particles, the ceramic slurry was formed into a sheet at the time of slip cast forming and a magnetic field was not applied to the ceramic slurry formed into a sheet, which resulted in insufficient orientation of the a axis, which is an easy axis, in a direction of application of magnetic field, in spite of orientation of the c axis in the direction of gravity.

Moreover, the sintered object of sample No. 16 had a degree of orientation of the c axis at the T plane which was as low as 0.103, although it had a high degree of orientation of the a axis, and the b axis at the S2 plane which was 0.230. This is because although ceramic slurry was slip cast formed in magnetic field, plate-shaped ceramic particles were not employed, which resulted in insufficient orientation of the c axis in spite of orientation of the a axis.

From the foregoing, it can be seen that piezoelectric ceramic in which all of three axes of crystallographic axes of piezoelectric ceramic particles are oriented can readily be obtained by forming ceramic slurry containing Bi₃TiNbO₉-0.08wt % MnO plate-shaped ceramic particles into a sheet by slip cast forming and applying magnetic field to the ceramic slurry formed into a sheet.

It is noted that this invention is not limited to the embodiments described previously and is variously modified within the scope of the gist thereof. Though the slip cast forming method has been described as the method of forming piezoelectric ceramic by way of example in the examples described previously, the method is not particularly limited thereto so long as a method is capable of aligning plate-shaped ceramic particles in layers. For example, a sheet forming method may be adopted. In particular, since the sheet forming method achieves alignment of plate-shaped ceramic particles in layers more readily than the slip cast forming method, the sheet forming method obtains piezoelectric ceramic higher in degree of orientation.

FIG. 24 is an illustrative configuration diagram for illustrating a forming step in a sheet forming method. A carrier film 20 like a tape is transported at a constant speed in the direction shown with arrow P by a pair of transportation rollers 28a, 28b. Ceramic slurry 1 is continuously applied onto this carrier film 20 to a prescribed thickness by using an application apparatus 22, to thereby form sheet-shaped ceramic slurry 1 with plate-shaped ceramic particles being aligned in layers. The direction of application of magnetic field B is set to one direction in substantially the same plane where sheet-shaped ceramic slurry 1 is located. In the present example, sheet-shaped ceramic slurry 1 is orthogonal to the direction of gravity and the direction of application of magnetic field B is set to a direction orthogonal (a direction perpendicular to a sheet surface) to a direction of transportation (direction of extension) P of sheet-shaped ceramic slurry 1 in substantially the same plane where sheet-shaped ceramic slurry 1 is located. A sintered object (piezoelectric ceramic) is obtained by firing the thus obtained compact at a prescribed temperature.

By employing a ceramic slurry containing plate-shaped ceramic particles, the c axis is oriented in the direction of gravity at the time of sheet forming, and in addition, by sheet forming the ceramic slurry in magnetic field, the a axis (the (100) axis), considered as an easy axis, is oriented in the direction of application of magnetic field. Consequently, three-axis-oriented piezoelectric ceramic in which the c axis is oriented in the direction of gravity at the time of sheet forming and the a axis is oriented in the direction of application of magnetic field is obtained.

It is noted that in the case of forming piezoelectric ceramic by pulling as the sheet forming method, the c axis at the T plane is oriented at least in a direction which is not the direction of gravity.

1. A piezoelectric ceramic containing plate-shaped ceramic particles in which
a degree of orientation of a first axis calculated with Lotgering method based on an X-ray diffraction pattern in a prescribed cross-section of said piezoelectric ceramic is not less than 0.30,
with a cross-section where the degree of orientation of said first axis indicates a maximum value being defined as a reference plane, a degree of orientation of a second axis calculated with the Lotgering method based on an X-ray diffraction pattern in a cross-section orthogonal to said reference plane is not less than 0.20, and
the degree of orientation of said second axis is represented by a value in such a cross-section that the degree of orientation of the second axis attains to a maximum value, among cross-sections orthogonal to said reference plane.

2. The piezoelectric ceramic according to claim 1, wherein said plate-shaped ceramic particles are free from shape anisotropy when viewed in a direction in parallel to a c axis.

3. The piezoelectric ceramic according to claim 2, wherein said plate-shaped ceramic particles have an average particle size not greater than 20 μm.

4. The piezoelectric ceramic according to claim 3, wherein said plate-shaped ceramic particles comprise a bismuth layered compound.

5. The piezoelectric ceramic according to claim 4, wherein said bismuth layered compound is selected from the group consisting of CaBi₄Ti₄O₁₅, CaBi₄Ti₄O₁₅-MnO, and CaBi₄Ti₄O₁₅.

6. The piezoelectric ceramic according to claim 4, wherein said bismuth layered compound has an aspect ratio of not less than 3.

7. The piezoelectric ceramic according to claim 1, wherein said plate-shaped ceramic particles have an average particle size not greater than 20 μm.

8. The piezoelectric ceramic according to claim 7, wherein said plate-shaped ceramic particles comprise a bismuth layered compound.

9. The piezoelectric ceramic according to claim 8, wherein said bismuth layered compound is selected from the group consisting of CaBi₄Ti₄O₁₅, CaBi₄Ti₄O₁₅-MnO, and CaBi₄Ti₄O₁₅.

10. The piezoelectric ceramic according to claim 9, wherein said bismuth layered compound has an aspect ratio of not less than 3.

11. The piezoelectric ceramic according to claim 1, wherein said plate-shaped ceramic particles comprise a bismuth layered compound.

12. The piezoelectric ceramic according to claim 11, wherein said bismuth layered compound is selected from the group consisting of CaBi₄Ti₄O₁₅, CaBi₄Ti₄O₁₅-MnO, and CaBi₄Ti₄O₁₅.

13. The piezoelectric ceramic according to claim 12, wherein said bismuth layered compound has an aspect ratio of not less than 3.

14. The piezoelectric ceramic according to claim 1, wherein said bismuth layered compound has an aspect ratio of not less than 3.

15. A method of manufacturing a piezoelectric ceramic, comprising:
providing a ceramic slurry containing plate-shaped ceramic particles;
forming said ceramic slurry into a sheet by sheet forming or slip casting; and
applying a magnetic field to sheet-shaped said ceramic slurry in a direction which is in a substantially identical plane to where the sheet-shaped ceramic slurry is located.

16. The method of manufacturing a piezoelectric ceramic according to claim 15 in which said ceramic slurry is formed into a sheet by sheet forming.

17. The method of manufacturing a piezoelectric ceramic according to claim 15 in which said ceramic slurry is formed into a sheet by slip casting.

18. The method of manufacturing a piezoelectric ceramic according to claim 15, further comprising preparing the ceramic slurry containing plate-shaped ceramic particles.

19. The method of manufacturing a piezoelectric ceramic according to claim 15, in which the plate-shaped ceramic particles comprise a bismuth layered compound.

20. The method of manufacturing a piezoelectric ceramic according to claim 19, wherein said bismuth layered compound is selected from the group consisting of CaBi₄Ti₄O₁₅, CaBi₄Ti₄O₁₅-MnO, and CaBi₄Ti₄O₁₅.
